(19) United States
(12) Patent Application Publication
(10) Pub. No.: US 2018/0130927 A1
(43) Pub. Date: May 10, 2018

(54) COMPONENT HAVING A TRANSPARENT CONDUCTIVE NITRIDE LAYER

(71) Applicant: OTTO-VON-GUERICKE-UNIVERSITÄT MAGDEBURG, TTZ PATENTWESEN, Magdeburg (DE)

(72) Inventors: Armin DADGAR, Berlin (DE); Axel HOFFMANN, Berlin (DE); Christian NENSTIEL, Regensburg (DE); André STRITTMATTER, Schwielowsee (DE)

(21) Appl. No.: 15/577,741

(22) PCT Filed: Jun. 4, 2016
(86) PCT No.: PCT/DE2016/000237

§ 371 Date: Nov. 28, 2017

(30) Foreign Application Priority Data
Jun. 4, 2015 (DE) 10 2015 108 875.4

(51) Int. Cl. H01L 33/42; H01L 33/02

(52) U.S. Cl. CPC H01L 33/42; H01L 51/442; H01L 33/025

(57) ABSTRACT

The invention relates to a component having a transparent conductive nitride layer, characterized by a layer in the AlGaInN system and a doping with a flat donor above a concentration of 5×1019 cm−3.

The invention relates to a component or a component module with a transparent conductive nitride layer.

Transparent conductive layers are irreplaceable for a variety of applications in microelectronics. For example, indium tin oxide (ITO) is widely used in display manufacturing. But even in solar cells they can be used as an electrically conductive cover layer. The main problem of the currently used ITO is the limited availability of indium, which is why recycling this material from used products is necessary to ensure the annual demand for this raw material. Another material available as an alternative is ZnO, which, doped with a group III element, allows for very high electron concentrations up to 10²¹ charge carriers per cm³ and thereby high electrical conductivities. However, ZnO is chemically quite unstable and easy to etch. Furthermore, it changes its material properties under atmospheric influence.

The Group III nitrides are nowadays mainly used for LED applications in the blue-green-white color space. For this application as well, ITO has hitherto been used as a conductive, transparent material in order to achieve an optimum current distribution over the p-doped region of the pn diode structure. The p-doped layer of the pn structure generally has a low conductivity in nitride semiconductors, which severely impairs current transport over several micrometers. So far, this problem is circumvented by a full-surface contact with a highly reflective in the visible spectral region, conductive metal (usually silver or aluminum) or by a transparent, conductive oxide layer, usually ITO.

Both solutions are disadvantageous because in the first case the choice of the contact metal is limited, whereby increased contact resistance at the junction metal/semiconductor occurs. In the second case, the ITO can only be deposited in a second process step as amorphous or polycrystalline material, because of which on the one hand costs are incurred and on the other hand only sub-optimal electrical and optical properties of the ITO can be achieved. It is now necessary to realize an improved contacting layer, which is less expensive and chemically more stable than previously used layers.

This object is achieved with a component according to claim 1 and a component module according to claim 6 as well as the embodiments of the dependent claims.

A component with a transparent conductive nitride layer is proposed, characterized by a layer in the system AlGaInN and a doping with a shallow donor above a concentration of 5×10¹⁹ cm⁻³.

A component is understood in the present invention as follows:
a light emitting component or
a light-absorbing component or
a light-transmissive component,
   each with a transparent conductive nitride layer.

The doping of the device should be carried out with a suitable group IV or group VI element such as a doping with germanium, tin, lead, sulfur and/or tellurium.

The simultaneous doping with multiple dopants is expressly possible in order to increase the conductivity and to circumvent the respective solubility limits. The doping of 5×10¹⁹ cm⁻³ can be seen as the lower limit, ideal is a doping above 1×10²⁰ cm⁻³. This makes it possible to achieve an ITO-like layer in terms of conductivity and transparency.

This layer requires for contacting usually only simple and not necessarily areal, but usually only small metal contacts, which also do not need to be alloyed for a small contact resistance. Depending on the doping level, the layer can also be contacted directly without a contact metal with a suitable bonding wire or other conductive material.

An embodiment of the invention provides that the contacting of the component by a transparent conductive nitride layer thereby takes place on at least one electrical connection of a component or a component of a component module.

In particular, the layer according to the invention is chemically and thermally very stable and thus also allows applications in which the surface is unprotected and for instance is exposed to aggressive media or, depending on the material, is exposed to temperatures up to 700° C. in case of the system AlₓGa₁₋ₓN with 0<x<1 or in case of In-containing systems slightly below, but still significantly above 200° C. Also, this layer is biocompatible when using the GaInN system, making it interesting as a contact layer to cells in biomedical research and for applications arising therefrom.

Another embodiment of the invention provides a device which is characterized by a tunnel contact between the transparent conductive nitride layer and a p-type device layer.

In the case of LEDs, the invention makes it possible to produce a tunnel contact between the transparent conductive nitride layer and a p-conductive component layer, which thus makes the use of ITO or other complex contacting methods superfluous and ensures good current distribution. Decisive for a low-resistance tunneling contact is the highest possible doping of the p-type and the n-type side, i.e. the p-type layer of the component which is to be contacted.

In the case of the group III nitrides with a hole concentration of at least 3×10¹⁷ cm⁻³, more preferably 5×10¹⁷ cm⁻³, and ideally 9×10¹⁷ cm⁻³ or above. The doping of the layer according to the invention is at least 5×10¹⁹ cm⁻³ and ideally over 1×10²⁰ cm⁻³.

The component may be applied to a group III nitride layer according to another embodiment of the invention.

Since the transparent conductive nitride layers are process compatible with the epitaxial processes for the production of LED structures, when applied to a group III nitride layer as in GaN based LEDs, additional process steps are dispensed with, such, for example: sputtering of ITO or ZnO. In addition, due to the good thermal and low to absent lattice mismatch, this layer is particularly long-term stable, since no or only small additional tensions are introduced into the device.

For deposition of the transparent conductive group III-nitride layer basically all suitable deposition methods such as, for example, plasma processes and evaporation processes come into consideration. Epitaxial methods are preferably to be used, as this achieves a low-defect material quality, which is advantageous for high conductivity.

With the hitherto used dopant silicon such a high electrically active doping is possible only with a few methods such as MBE, in particular, a rough surface forms using the most common method of the metalorganic vapor phase epitaxy. With the dopants according to the invention, even a slight smoothing of the surface is frequently made possible, which is advantageous for many applications.

In addition, a component module is proposed, which has at least one of the aforementioned components.

The invention is illustrated below by way of example with reference to embodiments and figures.

It shows:

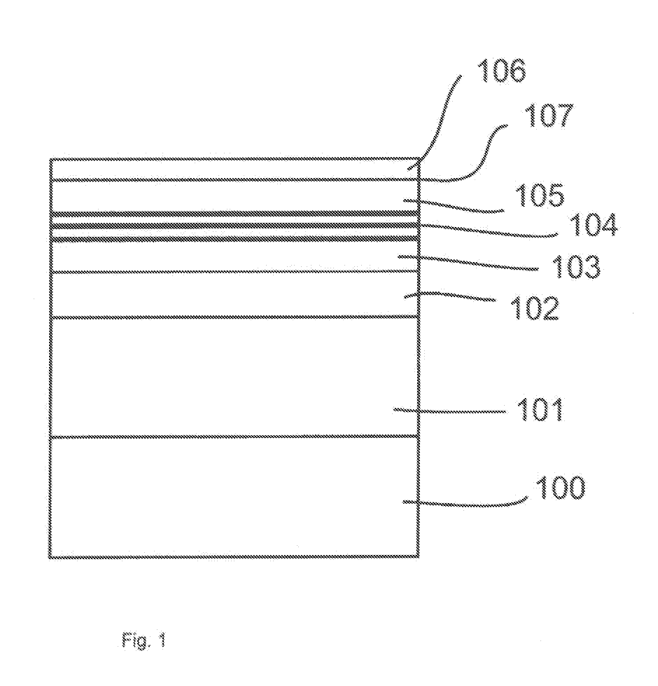

FIG. 1 schematically an LED structure in cross section,

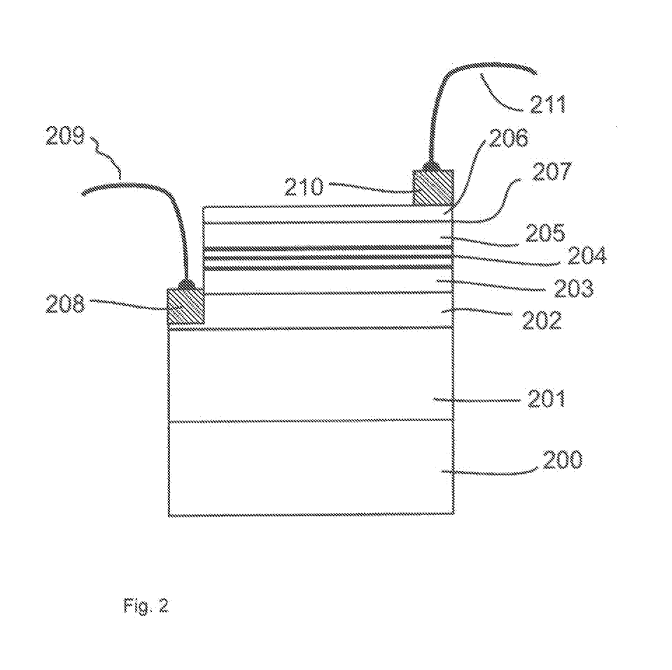

FIG. 2 schematically an LED structure with electrical connections in cross section

FIGS. 1 and 2 schematically show an LED structure in each case.

As shown in FIGS. 1 and 2, a simple LED structure comprises or consist of a substrate 100, 200, an optional seed and buffer layer 101, 201, an n-conductive layer 102, 202, which is ideally highly conductive, a further n-conductive layer, one or more light-emitting layers 104, 204, schematically shown here are three layers. This is optionally followed by an electron injection barrier, not shown, in group III nitrides made of AlGaN which is doped with Mg and typically has an Al concentration between 5-30% and a thickness between 5-25 nm.

The p-type layer 105, 205 is followed by the layer 106, 206 according to the invention, which can lead to a tunnel junction 107, 207 at the interface of the layers 105-106 and 205-206, respectively. The component is then introduced via metallizations 208 and 210 usually with wires 209, 211 in a circuit. For a group III nitride component, metallizations 208 and 210 may be identical. For other materials, this is not necessarily the case.

The structure of the layers or of the p-n junction can also be reversed, and the preferred light emission instead of upwards can take place downwards, through a substrate. In the latter case, the transparency of the upper layer plays only a role in that one can put a highly reflective layer behind it and still an excellent power distribution and contacting may be achieved.

In principle, the layer 106, 206 can be applied to any p-type layer of an LED, including LEDs made of materials other than a group III nitride, but also on n-type layers and generally in all types of components that have to be contacted, also solar cells and sensors.

This is generally advantageous for layers which require an optically transparent highly conductive cover layer. When GaN is used as the transparent conductive nitride, optical transparency in the visible to far beyond the infrared region is given. By adding Al to the UV range, where the conductivity with increasing Al content is usually lower and a tunnel contact is harder to achieve.

Another embodiment, in particular for component modules are displays. Here electrical contacts must be applied, which in the visible wavelength range must be transparent. For this purpose, a corresponding layer of e.g. GaN and a dopant according to the invention with the inventive concentration can be applied by epitaxial methods or sputtering. Either before applying a structuring with e.g. a subsequent lift off was intended or the layer is subsequently structured and wet or dry chemical separated into individual lines. The combination on an LED display which is monolithically grown on a substrate such as e.g. sapphire is ideal.

On the grown structure, the layer according to the invention is applied and patterned at the end of the growth process or, in particular for a multicolored design, in a second step. As a result, it is possible in principle to produce full-color LED displays on a group III nitride basis, which have great advantages in terms of service life due to the lattice-matched growth of the layer according to the invention and its high resistance to environmental influences.

The examples mentioned can be combined in any manner and relate to all production processes with which it is possible to produce doped group III nitride layers and to all types of components which require transparent conductive layers or which can advantageously be used for their properties.

1. Component with a transparent conductive nitride layer, wherein
the layer is in the system AlGaInN,
the layer is doped with a shallow donor above a concentration of 5×10¹⁹ cm⁻³.

2. Component according to claim 1, wherein the layer is doped with at least one of the following elements: germanium, tin, lead, sulfur, tellurium.

3. Component according to claim 1, characterized by contacting of at least one electrical connection of the component by the transparent conductive nitride layer.

4. Component according to claim 1, characterized by the application of the transparent conductive nitride layer to a group III nitride layer.

5. Component according to claim 1, characterized by a tunnel contact between the transparent conductive nitride layer and a p-type layer of a component.

6. Component module comprising at least one component with a transparent conductive nitride layer, wherein
the layer is in the system AlGaInN,
the layer is doped with a shallow donor above a concentration of 5×10¹⁹ cm⁻³.

7. Component module according to claim 6, wherein
the layer is doped with at least one of the following elements: germanium, tin, lead, sulfur, tellurium.

8. Component module according to claim 6, characterized by contacting of at least one electrical connection of at least one component of the component module by the transparent conductive nitride layer.

9. Component module according to claim 6, characterized by the application of the transparent conductive nitride layer to a group III nitride layer.

10. Component module according to claim 6, characterized by a tunnel contact between the transparent conductive nitride layer and a p-type layer of at least one component of the component module.
